(19) United States
(12) Patent Application Publication
(10) Pub. No.: US 2009/0161713 A1
(43) Pub. Date: Jun. 25, 2009

(54) SURFACE EMITTING OPTICAL DEVICES

(75) Inventors: Geoffrey Duggan, Enniskeane (IE); John Douglas Lambkin, Carrigaline (IE)

Correspondence Address: FISH & RICHARDSON P.C., PO BOX 1022, MINNEAPOLIS, MN, 55440-1022, US

(73) Assignee: FIRECOMMS LIMITED, Cork (IE)

(21) Appl. No.: 11/916,962

(22) PCT Filed: Jun. 2, 2006
(86) PCT No.: PCT/EP06/05388

§ 371 Date: Jul. 7, 2008

Related U.S. Application Data
(60) Provisional application No. 60/688,328, filed on Jun. 8, 2005.

(51) Int. Cl. H01S 5/00

(52) U.S. Cl. 372/45.01; 977/755

(57) ABSTRACT

A visible wavelength vertical cavity surface emitting laser suitable for single mode operation has an oxide aperture (81, 82) for concentrating electrical current within a central axial portion (143) of the device and a surface relief feature (144, 146) at an output surface of the device selecting for substantially single lateral mode of operation. The relationship between oxide confinement structure diameter (140) and surface relief feature diameter (141) has been mapped to provide optimum conditions for single mode behaviour and define a region of that space to produce optimum device performance in the visible device operating wavelength band between 630 nm and 690 nm.

The present invention relates to Vertical Cavity Surface Emitting Lasers (VCSELs), and in particular to such lasers that can be operated in a single transverse mode over a wide range of operating conditions.

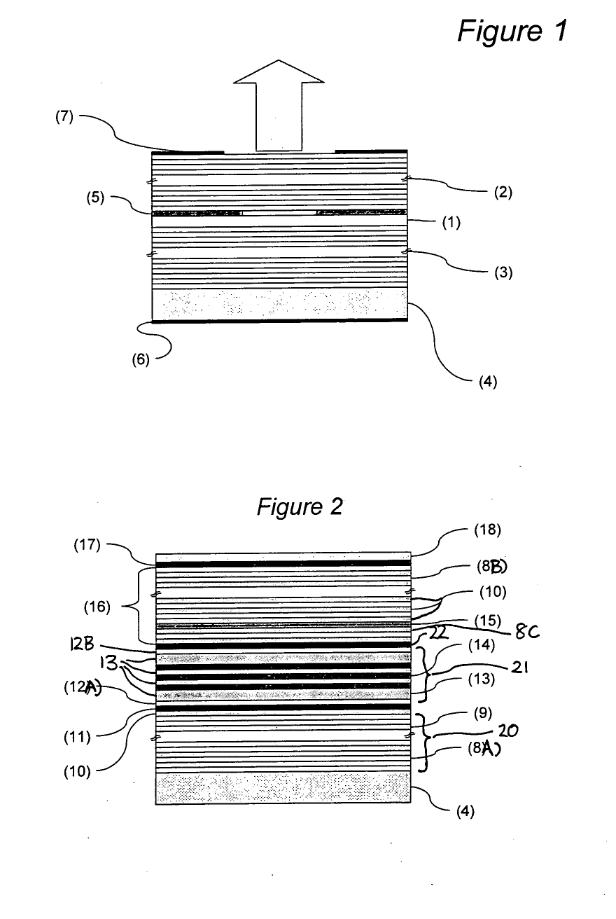

VCSELs differ from conventional edge emitting lasers in the respect that the resonant cavity is not formed by the natural cleavage planes of the semiconductor material but is formed by (usually) epitaxially produced Distributed Bragg Reflector (DBR) mirrors. For reference, a schematic diagram of a VCSEL is shown in FIG. 1. An active region 1 is sandwiched between a p-type DBR 2 and a highly reflecting n-type DBR 3. The device is grown epitaxially on, for example, a GaAs substrate 4. N and P-contacts 6 and 7 respectively conduct current through the device, the current being confined to a small volume by an oxide aperture 5. The cavity of the VCSEL is much smaller than that of an edge emitter—of the order of 1 wavelength (i.e. <1 micron)—compared to several hundred microns for a conventional edge emitter.

This small cavity size normally supports only one longitudinal lasing mode of the VCSEL. However, the lateral size of the device (sometimes in the order of 10 microns) means that the VCSEL supports many transverse modes. In many applications, e.g. transmission over Plastic Optical Fibre (POF) and holographic storage, it is essential that the VCSEL operates in a regime where it supports only a single longitudinal and transverse mode, over as wide a range of operating temperatures and drive currents as possible.

There have been several published papers detailing approaches to try to improve the polarization and single mode properties of infra-red (IR) VCSELs (with wavelengths in the range 850 nm to 980 nm). The inventors are not aware of any published attempts to improve the single mode behaviour of VCSELs operating in the visible portion of the spectrum. Of principal concern is the portion of the spectrum having wavelengths in the range 630 nm to 690 nm where the active region of the device is made from quantum wells (QWs) and heterostructures made from the (Al, Ga) InP semiconductor materials system.

Usually the length of resonant cavity of a VCSEL is of the order of 1 wavelength (1 λ, but extending this cavity by the addition of a suitable spacer layer (see references [1], [2]) has been shown to reduce the far field angle of the light beam and extend single mode behaviour over a wider operating current range. Increased single mode output power and larger area single mode operation, due to increased diffraction losses for higher order transverse modes. are observed [1]. One disadvantage of this technique is the increased possibility that more than one longitudinal mode can be supported within the extended cavity. This increases the possibility that the wavelength of the VCSEL will hop between one longitudinal mode and the other as the junction temperature of the device increases [2].

Nishiyama et al [3] demonstrated enhanced single mode operation in a 960 nm VCSEL using a Multi-Oxide (MOX) Layer structure. Here, the addition of three mode suppression layers above the current confinement layer is used. These layers have oxide apertures which are 1 to 2 microns larger in diameter than that of the current confinement aperture. Optical mode profiles of the higher order modes are wider than the fundamental transverse mode. The mode suppression apertures need to be chosen in such a way that they are wider than the profile of the fundamental mode and smaller than that of the higher order transverse modes. In this way they only act to increase the scattering loss of the higher order modes and thus promote single mode behaviour. Whilst the MOX approach is conceptually simple it is very demanding upon the amount of control required to make the structures. It is well known that the oxidation rate of Al(x)Ga(1-x)As increases exponentially as the Al-mole fraction increases beyond x˜0.94 [4]. The need to accurately control the aperture sizes means that it is essential to accurately control the Al-mole fraction during epitaxial growth and to ensure that the oxidation uniformity across a wafer can be maintained for both of the necessary Al-mole fractions. It would be most unlikely that this technique be applied in a mass production environment.

In general, restricting the gain to a small central region is a useful technique to enhance polarisation control and single mode behaviour in oxide confined VCSELs. Inter-diffusion [5], implantation disordering of the QWs [6, 7] and an additional implant of the top mirror [8] has achieved single mode output powers of 5 mW. Just like the MOX technique, all of these approaches require crucial alignment of the two aperture types which makes these techniques not really suitable for mass production.

Most recently, so called photonic bandgap (PBG) [9, 10] VCSELs, operating at 850 nm, have been fabricated showing promising single-mode behaviour. These devices seek to achieve single mode behaviour by creating an effective step in refractive index across the surface of a conventionally etched and oxidised VCSEL. The step is achieved through a second photolithographic and etching step which etches a series of holes thru the top p-DBR. The holes are arranged on a periodic lattice with one “defect”, i.e. no-hole being left at the centre of the mesa. As an example, single mode behaviour is achieved in reference [9] using a hole pitch (Λ) of 5 microns and a hole diameter (a) to pitch ratio of (a/Λ)=0.3.

Self-aligned surface relief techniques [11, 12] have been used previously to successfully demonstrate high power, single mode behaviour from large oxide aperture, 850 mn VCSELs. Within this category of devices there are two ways to achieve the desired single mode behaviour. One approach, which is the most pursued method, is to etch a shallow structure in the shape of an annulus in an otherwise conventional VCSEL structure, thereby increasing the losses of higher order modes [13]. The second way is to add an extra layer one quarter wavelength (λ/4) thick on the top of the conventional VCSEL during the epitaxial growth [10]. As Haglund et al point out [12], the advantage of the latter approach is that it utilizes the high thickness precision in the epitaxial growth to reach a narrow local maximum in the mirror losses. This will then relax the required etch depth precision since the required etch precision required since the minimum in the mirror reflectivity is much broader.

When designing and realising an oxide confined VCSEL with a mode selecting surface relief structure it is likely that there exists an optimum combination of oxide aperture diameter, relief diameter and etch depth. This parameter space has been explored theoretically by Vukusic et al [14] for shallow etched 850 nm VCSELs. No such study has been carried out for the more production tolerant “deep” etched surface relief variant although a smattering of results exist for a combination of oxide apertures and surface relief diameters. However, there is no systematic study for 850 nm devices. Based solely on the AlGaAs materials combinations it is not obvious. even to one skilled in the art, how to choose the optimum combination of oxide diameter, etch depth and relief diameter for the high power operation of single mode device operating in the 630 nm to 690 nm visible region of the spectrum and based on active regions incorporating the AlGaInP materials system.

It is an object of the present invention to provide a VCSEL device that operates in the visible wavelength spectrum and which operates in a single transverse mode over a wide range of operating conditions.

According to one aspect, the present invention provides a vertical cavity surface emitting optical device comprising a cavity adapted for generating optical output having a wavelength in the range 630 nm to 690 nm, the device including an oxide aperture for concentrating electrical current within a central axial portion of the device and a surface relief feature at an output surface of the device adapted to select substantially a single lateral mode of operation.

Embodiments of the present invention will now be described by way of example and with reference to the accompanying drawings in which:

FIG. 1 is a schematic cross-sectional diagram of a conventional VCSEL structure;

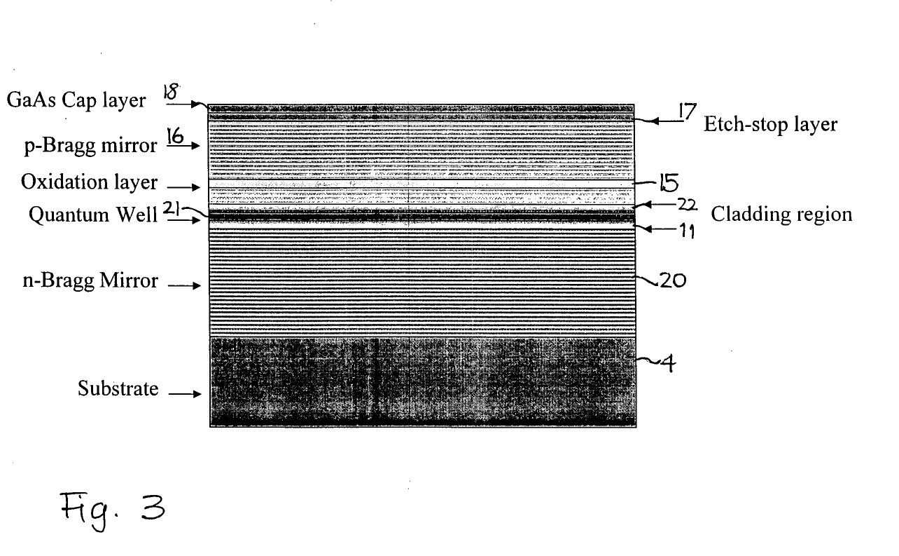

FIG. 2 is a schematic cross-sectional diagram of an epitaxial layer structure suitable for forming a VCSEL operable in the visible spectrum;

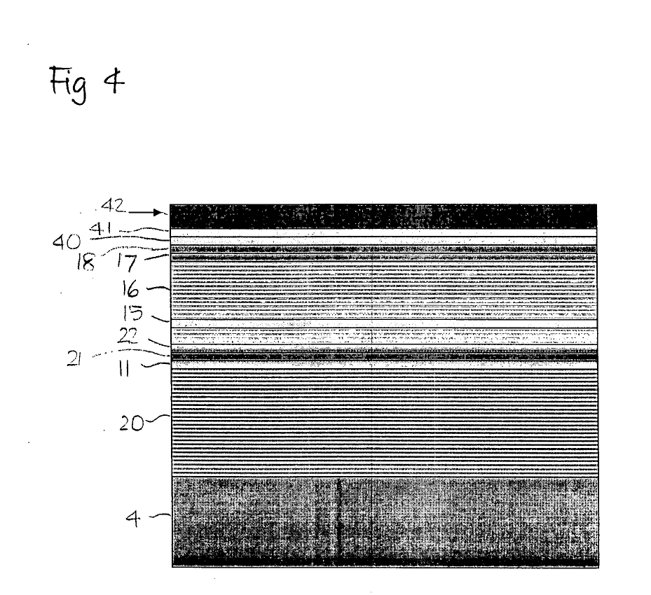

FIGS. 3 to 13 show cross-sectional schematic views of a VCSEL during various stages of manufacture;

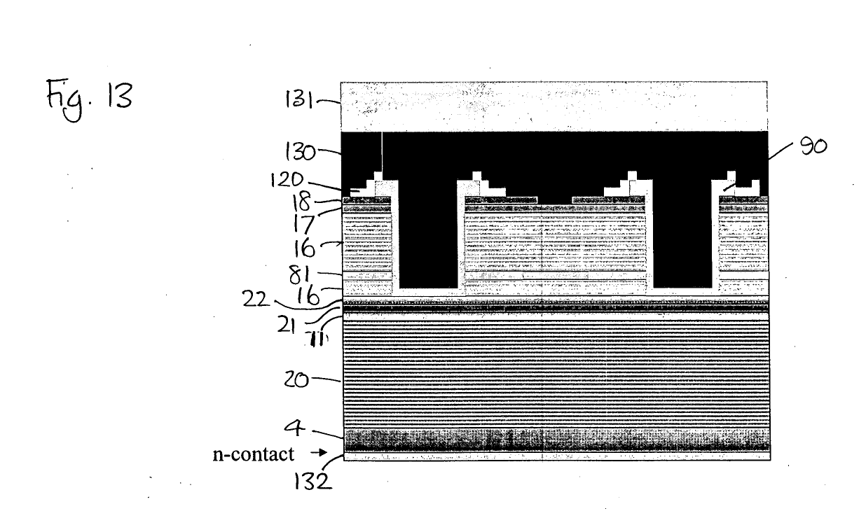

FIG. 14 shows a cross-sectional schematic side view of a VCSEL fabricated in accordance with the invention;

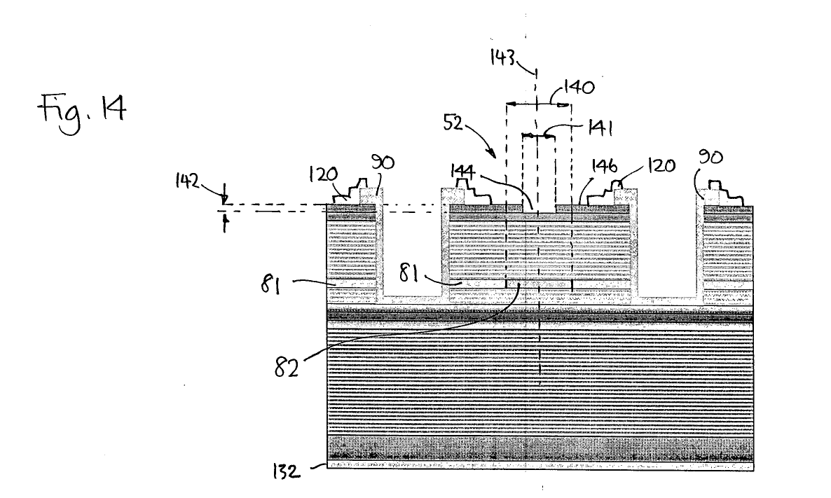

FIG. 15 is a light intensity vs. drive current characteristic for a 680 nm device fabricated according FIG. 14;

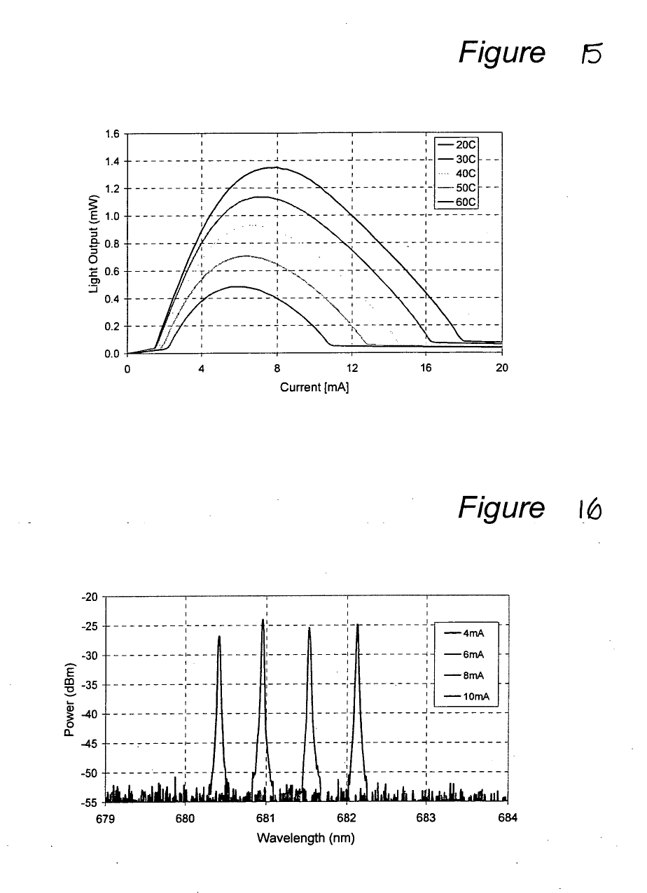

FIG. 16 illustrates the relationship between laser power output and wavelength for varying drive currents of the device fabricated according to FIG. 14;

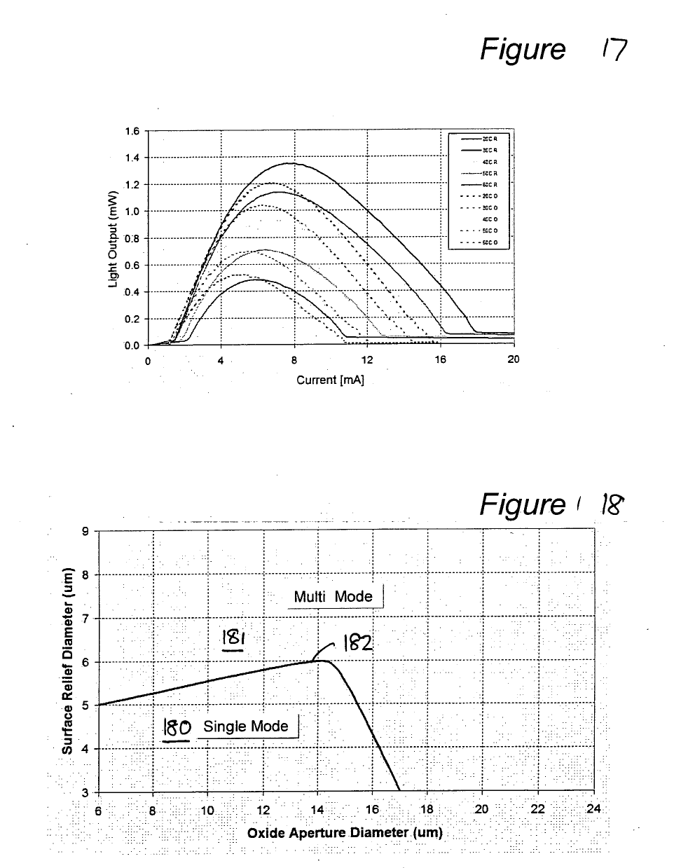

FIG. 17 illustrates the relationship between light output and drive current at varying temperatures of operation (i) for a device according to the present invention. contrasted with (ii) a device according to the prior art;

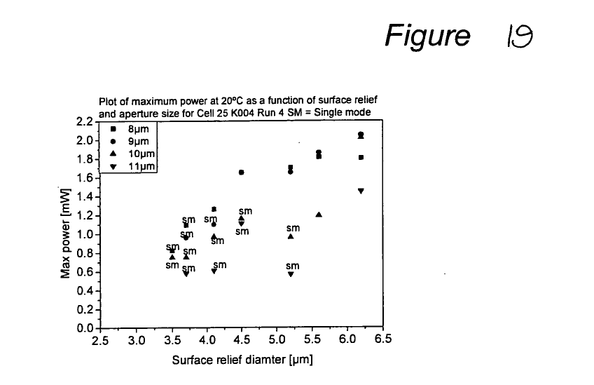

FIG. 18 illustrates the parameter space of surface relief diameter and oxide aperture, defining those regions of this space in which single mode operation is obtained; and

FIG. 19 illustrates power available from a device as a function of surface relief diameter for various oxide aperture diameters.

A schematic of an epitaxial layer structure suitable for forming a VCSEL device operable for visible wavelength radiation is shown in FIG. 2. In exemplary embodiments, epitaxial structures and devices are produced by the growth technique of metal-organic chemical vapour deposition (MOCVD) which is also referred to as metal-organic vapour phase epitaxy (MOVPE) [15]. However, other growth methods may be used in alternative embodiments. Similar device results could be obtained using molecular beam epitaxy (MBE) or one of its variants, e.g. gas source MBE which is used successfully in the commercial manufacture of, for example, edge emitting 650 nm band, DVD laser diodes.

The epitaxial layers of FIG. 2 are deposited on an n-type GaAs substrate 4 which is misoriented from the conventional (001) plane by 10 degrees towards the <111A> direction. The use of a misoriented substrate is preferred to obtain the highest quality epitaxial layers and the 10 degree angle is preferred. However, excellent results could still be expected using orientations between 6 degrees and 15 degrees [16, 17]. In other embodiments, successful results can be obtained using substrates oriented in the (311)A plane [18].

In the preferred embodiment, an n-type distributed Bragg reflector (DBR) mirror 20 (hereinafter also referred to as the n-DBR) has 55 pairs of alternating λ/4n layers 9, 8A of AlAs/Al(0.5)Ga(0.5)As, where λ is the wavelength of interest and n is the refractive index of the constituent layer at the wavelength of interest. In this example, the layer thicknesses are chosen to maximise the reflectivity of the stack at a centre stop-band wavelength of 680 nm. A linear grading of the Al-mole fraction at the interfaces between the two layers is also preferred. The alternating layers 9, 8A are doped with Si using a gas flow appropriate to produce a doping of ˜1×10¹⁸ cm⁻³. The DBR stack 20 is close to lattice matching the GaAs substrate 4. On the upper layer of the DBR stack is a layer 10 of Al(0.95)GaAs and a diffusion barrier layer 11 of AlInP which is n-doped (Si˜1-5×10¹⁷ cm⁻³). The doping level in this layer 11 is reduced in comparison to the DBR layers 9, 8A as an attempt to minimise any diffusion of Si toward the active region of the device in the subsequent growth of the following layers as this could have a deleterious affect on device performance.

On top of layer 11 is grown a 1 λ/n cavity 21 which is similar in design to that of a separate confinement heterostructure (SCH) of an edge emitting laser diode. In the preferred embodiment, three compressively strained InGaP quantum wells 14 each of ˜9 nm thickness are used. The wells 14 are separated by lattice matched barriers 13 of Al(0.5)GaInP and the cavity 21 is completed by further barriers 12A, 12B of Al(0.7)GaInP, doped n and p respectively. The thickness of the Al(0.5)GaInP layers 13 is chosen such that the wells are quantum mechanically isolated and the outer Al(0.7)GaInP layers 13 chosen to fulfil the criteria of forming a 1 λ/n cavity. The next layer is a further AlInP spacer layer 22 that helps prevent electron leakage as the temperature increases. Ideally this layer 22 should be as heavily doped as possible to maximise the barrier for electron leakage but in practice the designer is limited due to the requirements that (a) Zn has to be used as the p-type dopant in the p-containing materials and (b) dopant should not diffuse into the active region. In a preferred design, a p-type doping level of ˜1-5×10¹⁷ cm⁻³ is used. Secondary Ion Mass Spectrometry (SIMS) on samples grown using these n- and p-type doping levels in the AlInP confirms that no dopant has diffused into the active region.

Increased read and write speeds of DVD R/W drives have been achieved by increasing significantly the power available from an edge emitting laser. In part, reliable high power and high temperature operation has been realised by the use of Mg in place of Zn. Mg has a significantly lower probability of diffusion and could therefore be used in larger concentrations in spacer layer 22.

A p-type DBR-mirror 16 has 35 pairs of Al(0.95)GaAs/Al(0.5)GaAs layers 10 and 8B with the exception of the second pair 15, 8C which is made from Al(0.98)GaAs/Al(0.5)GaAs to facilitate the formation of an oxide aperture of appropriate dimension, to be described later. Two further layers are added: (i) an InGaP etch stop layer (ESL) 17 and (ii) a λ/4n GaAs antiphase layer 18. In alternative embodiments, the etch stop layer 17 is AlGaInP and the antiphase cap layer 18 is InGaAs.

With reference to FIGS. 3 to 13, a particularly preferred method of fabrication of the VCSEL devices comprises the following steps. It will be understood that this process is exemplary only.

FIG. 3 illustrates, in somewhat simplified form, the layered structure of the starting material prior to lithographic processes. This figure corresponds to that described in connection with the more detailed FIG. 2, using corresponding reference numerals.

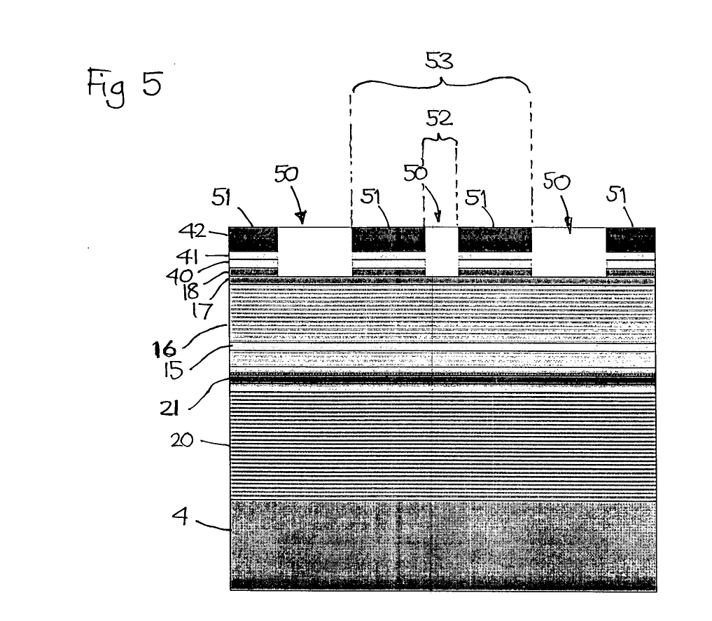

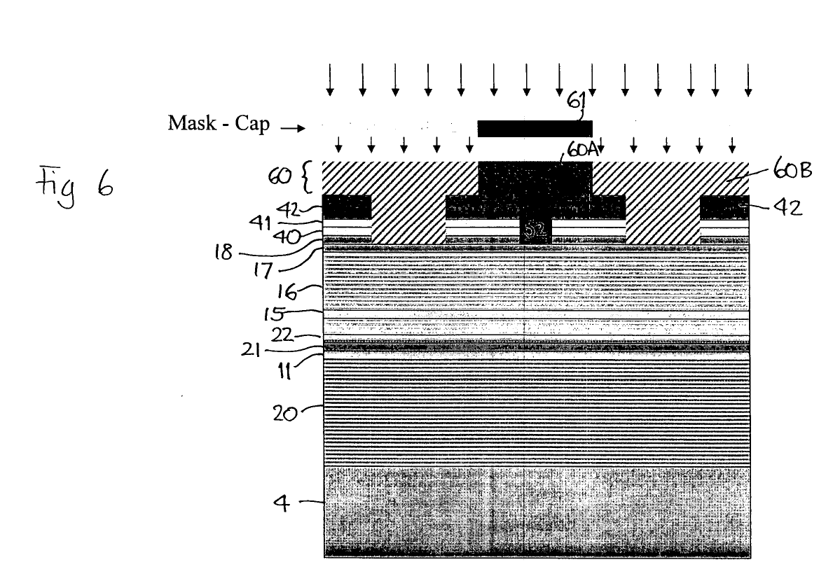

With reference to FIG. 4, a thin layer 40 (e.g. 50 nm thickness) of SiO₂ is deposited using PECVD. This oxide layer 40 is coated with adhesion promoting material such as HMDS 41 using known coating and bake processes. The HMDS layer 41 is then coated, using conventional spin coating techniques, with a photoresist layer 42. The result of the first photolithographic step is shown in FIG. 5. A photo mask (not shown) is used to expose regions 50 of the photoresist layer 42 which are then developed and removed as shown to leave photoresist 42 in the unexposed regions 51. This photoresist mask is then used during an etch of the oxide layer 40 using, for example, a buffered oxide etch (BOE). The GaAs antiphase layer 18 is also etched through photoresist mask 51, using an appropriate wet or dry etch.

This first photolithographic step simultaneously defines the surface relief feature 52 and the diameter of the mesa structure 53 in the protective SiO₂ layer 40 and GaAs cap layer 18.

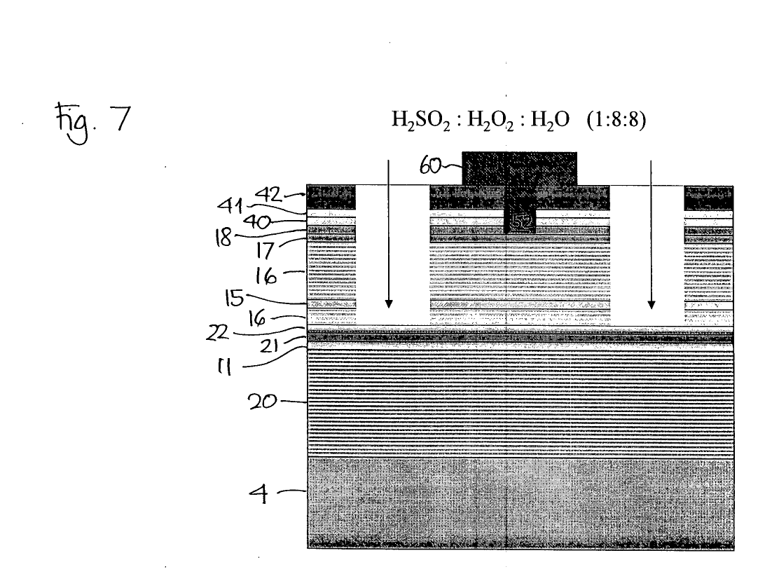

With reference to FIG. 6, a further layer of photoresist 60 is deposited to fill the exposed regions 50 and cover existing resist regions 51. This is exposed using a mask 61 that protects the surface relief feature 52. The photoresist area 60B (shown shaded) is developed away leaving protective region 60A, together with the remaining underlying photoresist layer 42.

In the next step, the exposed surfaces of the InGaP etch stop layer 17 are dry etched, together with the top part of the p-type DBR mirror 16 to define the mesa structure. A separate wet etch is used to etch the oxidation layer 15 (Al(0.98)GaAs) and the remaining (underlying) p-type DBR mirror 16 layers, leaving the structure as shown in FIG. 7. The wet etch stops at the AlInP spacer layer 22 that defines the resonant cavity.

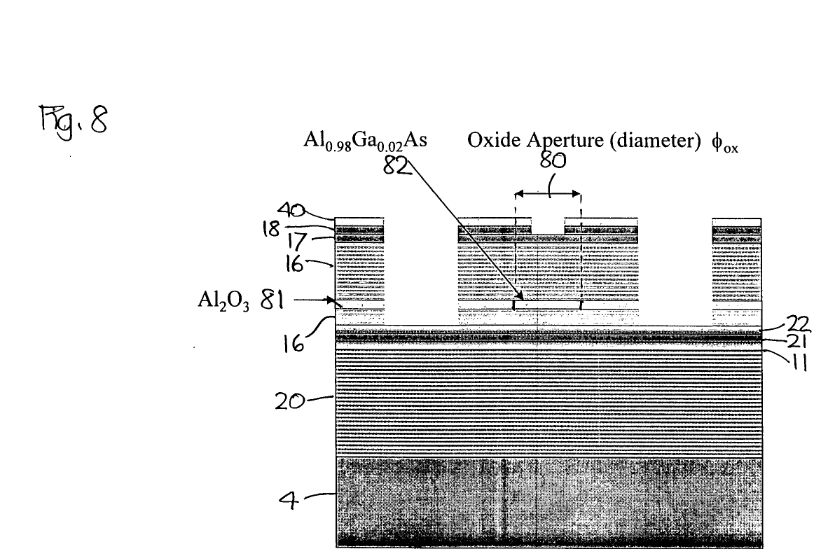

The photoresist layers 42 and 60 are then removed using an appropriate wet etch. The next step is a timed steam oxidation to define the oxide aperture 80 as shown in FIG. 8. The oxide aperture is formed by lateral oxidation of the Al(0.98)GaAs oxidation layer 15 thereby forming an oxide (AlOₓ) layer 81 but leaving a central region 82 of the unoxidised Al(0.98)GaAs layer 15.

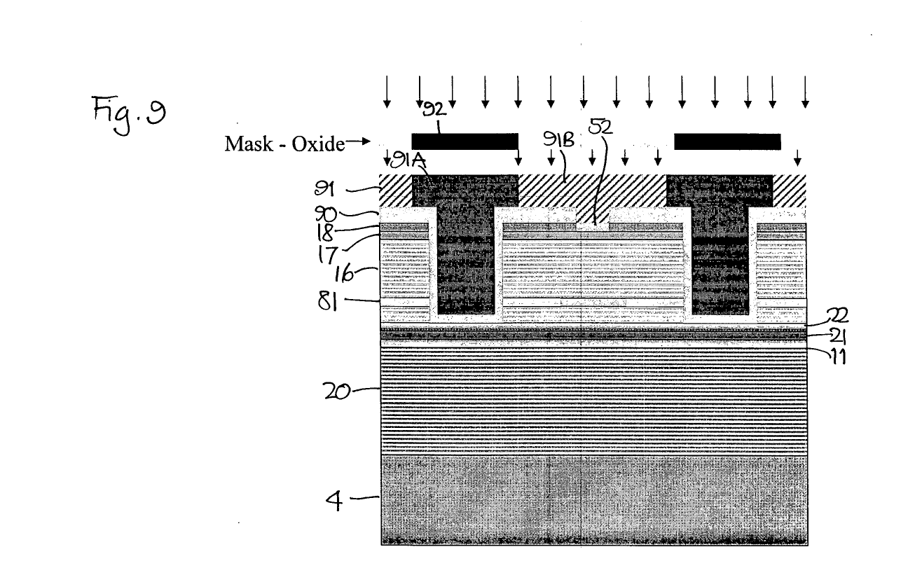

With reference to FIG. 9, there follows deposition of a PECVD SiO₂ layer 90 which acts as a sidewall passivation layer for the exposed oxidised layers. In a preferred process, the SiO₂ layer is about 200 nm thick. A third photoresist layer 91 is deposited and exposed using mask 92 to leave photoresist regions 91A and develop away photoresist regions 91B (shown shaded). The mask 92 is aligned to the centre of the surface relief feature 52.

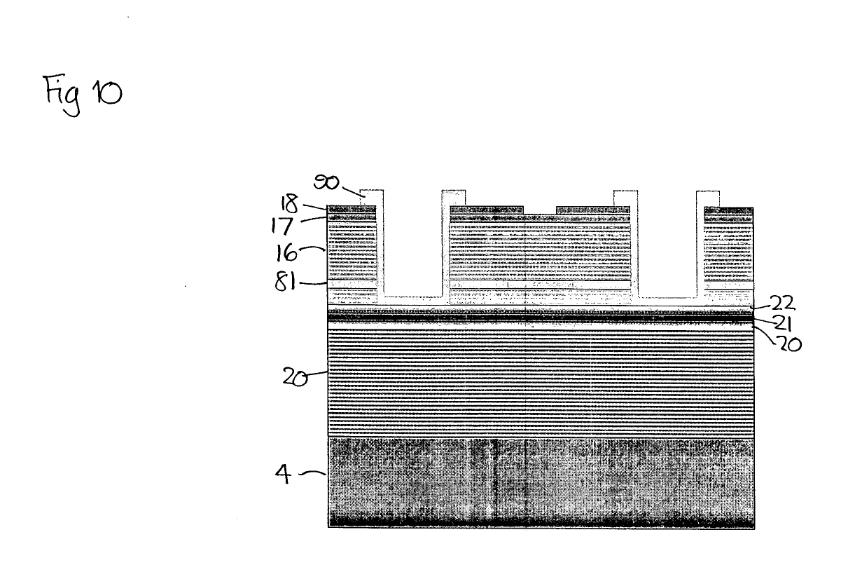

Using the photoresist regions 91A as a protective mask, the exposed PECVD SiO₂ layer 90 is etched together with the underlying oxide layer 40, e.g. in a buffered oxide etch. After removal of the photoresist 91A, this leaves the structure shown in FIG. 10, ready for photolithography to define the p-contact.

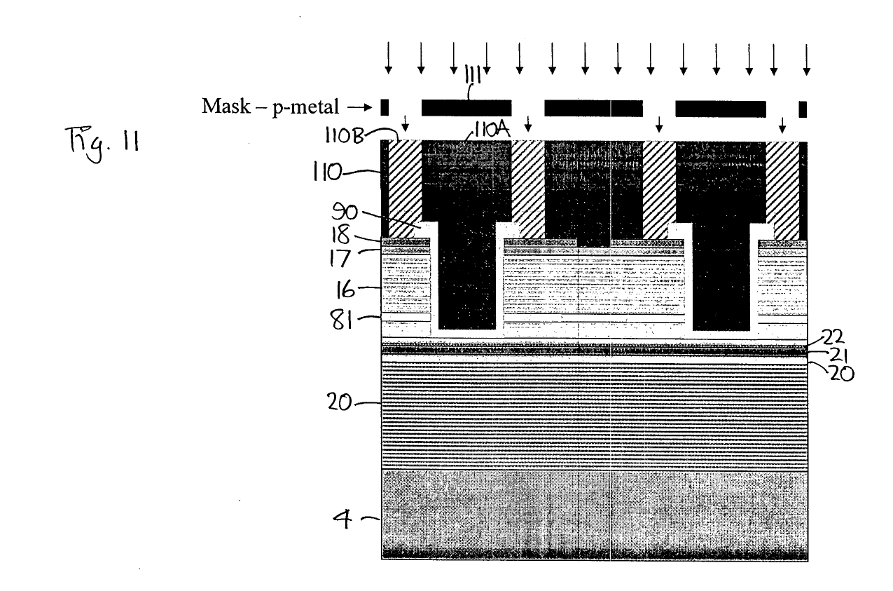

With reference to FIG. 11, first and second layers of photoresist 110 are deposited and exposed using photo mask 111 for definition of a p-metal contact. The photoresist regions 110A remain after exposure and developing while the photoresist regions 110B (shown shaded) are removed after developing.

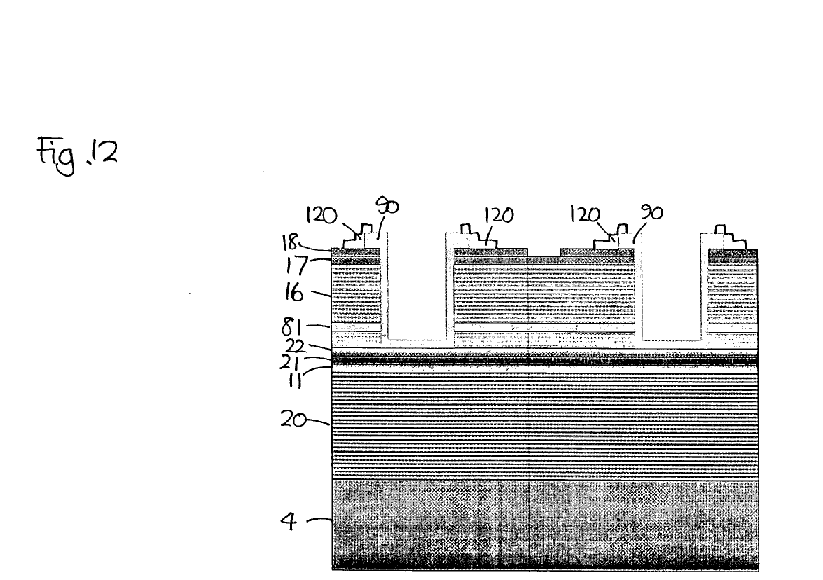

Deposition of the p-contact metals then takes place. In a preferred process, the p-metal contact is formed from evaporation of Ti. Pt and Au metals, by a layered metallization 120 of 30 nm Ti, 40 nm Pt. and 300 nm Au, in that order. The photoresist 110A is then removed also lifting off any metallization deposited thereover, leaving the structure as shown in FIG. 12.

This structure is then coated in black wax 130 (FIG. 13) and attached, top side down, to a glass substrate 131 so that the underside of the structure can be processed. During the underside processing, the GaAs substrate 4 is thinned to approximately 120 microns using bromine methanol. An n-metal contact 132 is evaporated onto the underside of the substrate 4. Preferably, the n-metal contact deposition comprises a layered metallization of 170 nm Ge, 50 nm Au, 10 nm Ni, 150 nm Au, in that order.

The glass substrate 131 and protective black wax layer 130 are then removed and the contacts annealed, e.g. at 380 degrees C.

A finished VCSEL device is illustrated schematically in FIG. 14, identifying critical dimensions of the device. The oxide aperture diameter 140 represents the diameter of the unoxidised Al(0.98)GaAs layer 82 (see also FIG. 8). The surface relief feature diameter 141 represents the diameter of the feature etched into the GaAs cap layer 18 (see FIG. 5). The surface relief feature step height 142 represents the thickness of the GaAs layer 18, preferably a quarter wavelength (λ/4n), or odd multiples thereof such as 3λ/4n, 5λ/4n, 7λ/4n etc. Both the surface relief feature and the oxide aperture are preferably circular, coaxial and centred on the central optical axis 143 of the device. However, departure from a circular, coaxial formation of both oxide aperture and surface relief feature is possible while still obtaining single transverse mode operation. Thus, non-circular and/or non-axially aligned surface relief features and oxide apertures may be used.

The electrical and optical characteristics of the fabricated devices are shown in FIGS. 15 to 17.

FIG. 15 shows an illustrative example of the L-I (light intensity versus drive current) characteristic from a device prepared using the process described above. Emission is at approximately 680 nm wavelength and the device is capable of single mode behaviour up to 60 degrees C. FIG. 16 illustrates the relationship between laser power output and wavelength for varying drive currents and demonstrates the nature of the single mode spectrum, at 20 degrees C., for that variety of drive currents. It will be noted that the operation of the device remains substantially single moded at drive currents in the range 4 to 10 mA.

FIG. 17 contrasts devices made using the preferred method described above with a device manufactured using only a small oxide aperture. The curves shown in unbroken lines are reproduced from FIG. 15 where the oxide aperture diameter 140 is approximately 8 microns and the surface relief feature diameter 141 is approximately 3.5 microns. The dotted lines illustrate corresponding L-I curves from device where the oxide aperture is only 4 microns in diameter. In general the single mode power available from using the surface relief feature 52 and oxide aperture 80 is higher than that of just a small, oxide aperture. The variation of optical power with temperature is marginally worse for a surface relief VCSEL, but only marginally. Any change in this property is far outweighed by the ability to fabricate these devices in a much more controlled manner compared to trying to oxidise reproducibly a 3 to 4 micron aperture.

The inventors have determined, for VCSELs operable in the visible optical spectrum of 630 to 690 nm wavelength, optimum dimensions of the surface relief feature 52 and oxide aperture 80 parameter space in which devices will provide good single mode performance.

FIG. 18 shows a graphical ‘map’ of the parameter space or area in which particularly good single mode performing devices can be found, as a function of surface relief diameter 141 and oxide aperture 140. Devices that operate in a single mode at >40 degrees C. can be found using surface relief diameters in the range 3 to 5 microns and oxide apertures in the range 6 to 15 microns. FIG. 19 illustrates this point in a different manner. FIG. 19 uses the oxide aperture diameter 140 as a parameter and plots the power available from the device at a drive current of 7 mA, at 20 degrees C., as a function of the surface relief diameter 141. Appropriate data points are labelled to indicate when the spatial modal property of the tested device changes from single to multi-mode. Although there is scatter in the data, there is a clear trend of increasing power output as the surface relief diameter becomes a larger proportion of the oxide aperture area. However, this trend cannot continue indefinitely and at some point the device changes to multimode output. This plot makes it clear that manufacturable devices with good output powers and excellent spatial properties can be obtained with a surface relief to oxide aperture ratio of about two. Specifically, excellent device performance can be obtained when the surface relief diameter is in the range 4.8 to 5 microns and the oxide aperture is in the range 8 to 9 microns.

More generally, it has been determined, as shown graphically in FIG. 18, that single mode operation is optimised in 630 to 690 nm wavelength devices in the region 180 below the curve 182 whereas multimode operation occurs in the region 181 above the curve 182. Thus, single mode operation is optimised when:

y≦x/8+4.25, and a)

y≦−4x/3+25.67, b)

where x is the oxide aperture in microns and y is the surface relief diameter in microns. More preferably, the surface relief diameter is greater than 3 microns and the oxide aperture is greater than 6 microns.

Alternatively, single mode operation is optimised in 630 to 690 nm wavelength devices in the (x,y) space bounded by (6,3), (6,5), (14,6) and (17,3), where x is the oxide aperture in microns and y is the surface relief diameter in microns.

As detailed above, the preferred process used to form the surface relief feature 52 does not use a shallow etch process within an upper layer 17, 18 but rather uses the more tolerant method of completely removing the λ/4n GaAs antiphase layer 18 etched stopped against the InGaP layer 17. in the centre of the mesa. However, either technique may be used.

The thin InGaP etch stop layer is usually tensile strained and the InGaP composition is chosen to enhance the selectivity of chemical etching between AlGaInP and InGaP. As the wavelength of the device approaches 630 nm, the InGaP advantageously can be replaced with AlGaInP which has a higher bandgap than InGaP. The GaAs quarter-wave antiphase layer is the most straightforward example of a layer with an appropriately larger refractive index that allows the “deep etching” surface relief devices. However, it has been noted that the GaAs is absorptive at the proposed wavelengths of operation and increases the differential resistance of devices. In the example device results presented here, GaAs is used as the contact and anti-phase layer but the use of almost lattice matched InGaAs could be used advantageously since the absorption coefficient of InGaAs is close to that of GaAs for small In mole fractions and the reduction in band gap by adding small amounts of In will result in a better Ohmic contact and give some reduction in the overall resistance of the device.

Although the preferred embodiments described above use a surface relief feature 52 comprising a surface recess 144 at the central optical axis 143 of the VCSEL (i.e. a central low relief portion), it will be understood that in other embodiments, the surface relief feature 52 may comprise an upstanding relief feature (i.e. a central high relief portion). For example, the surface relief feature may comprise a raised portion of diameter 141 surrounded by an annular lower surface.

More generally, the surface relief feature 52 is any relief feature that provides on-axis selectivity to the single lateral mode central maximum in preference to the off-axis maxima of higher order lateral modes. Preferably, the surface relief feature provides a quarter wavelength difference in optical path length (parallel to the optical axis 143) between the central portion of diameter 141 and an annular outer portion 146.

In preferred embodiments, the surface relief feature has a height in the range 40 nm to 46 nm. More generally, the surface relief feature has a height of approximately λ/4n where λ lies in the range 630 nm to 690 nm and n is the refractive index of the material in which the surface relief feature is formed (e.g. GaAs or InGaAs) at the wavelength λ. Still more generally, the surface relief feature has a height of approximately mλ/4n where λ. lies in the range 630 nm to 690 nm, m is an odd integer, and n is the refractive index of the material in which the surface relief feature is formed (e.g. GaAs or InGaAs) at the wavelength λ.

In another embodiment, the optical device as described in connection with FIGS. 1 to 14 could be inverted. In other words, the substrate 4 would be a p-type substrate, DBR stack 20 would be a p-type mirror, and DBR stack 16 would be an n-type mirror. In some circumstances, this arrangement may assist with heat dissipation and could be advantageous.

Other embodiments are intentionally within the scope of the accompanying claims.

### REFERENCES

[1] H. J. Unold, S. W. Z. Mahmoud, R. Jager, M. Kicherer, M. C. Reidl and K. J. Ebeling, “Improving single-mode VCSEL performance by introducing a long monolithic cavity”, IEEE Photon. Tech. Lett, Vol. 12, No. 8, pp. 939-941, 2000

[2] D. G. Deppe and D. L. Huffaker, “High Spatial coherence vertical-cavity surface emitting laser using a long monolithic cavity”, Electron. Lett. Vol. 33, No. 3, pp. 21-213, 1997

[3] N. Nishiyama, M. Arai, S. Shinada, K. Suzuki, F. Koyama and K. Iga, “Multi-oxide layer structure for single-mode operation in vertical-cavity surface emitting lasers”, IEEE, Photon Tech. Lett. Vol. 12, No. 6, pp. 606-608, 2000

[4] K. D. Choquette, K. M. Geib, C. I. H. Ashby, R. D. Twesten, O. Blum, H. Q. Hou, D, M. Follstaedt, E. Hammons, D. Mathes and R. Hull, “Advances in Selective Wet Oxidation of AlGaAs Alloys”, IEEE Journal of Selected Topics in Quantum Electronics, vol. 3, pp. 916-926, 1997.

[5] R. L. Naone, P. D. Floyd, D. B. Young, E. R. Hegblom, T. A. Strand and L. A. Coldren. “Interdiffused quantum wells for lateral confinement in VCSELs”, IEEE J. Select. Topics Quantum Electron., vol. 4, pp. 706-714, 1998

[6] K. D. Choquette, K. M. Geib, R. D. Briggs, A. A. Allerman and J. J. Hindi, “Single Transverse Mode selectively oxidised vertical cavity lasers”, in Vertical Cavity Surface Emitting Lasers IV, C. Lei and K. D. Choquette, Eds: Proc SPIE, 2000, vol. 3946, pp. 230-233

[7] K. D. Choquette, A. A. Allerman, K. M. Geib and J. J. Hindi, “Lithographically defined gain apertures with selectively oxidised VCSELs”, in Proc. Conf on Lasers and Electro-Optics, May 2000, pp. 232-233

[8] K. D. Choquette, A. J. Fischer, K. M. Geib, G. R. Hadley, A. A. Allerman and J. J. Hindi, “High single mode operation from hybrid ion implanted selectively oxidised VCSELs”, in Proc. IEEE 17^{th} Int. Semiconductor Laser Conf., Monterey, September 2000, pp. 59-60

[9] D-S. Song, S-H Kim, H-G Park, C-K Kim and Y-H Lee, “Single Fundamental Mode Photonic Crystal vertical cavity surface emitting lasers”, Appl. Phys. Lett, vol. 80, pp. 3901-3903, 2002

[10] A. J. Danner, J. J. Rafferty, N. Yokouchi and K. D. Choquette, “Transverse modes of photonic crystal, vertical cavity lasers”, Appl. Phys. Lett, vol. 84, pp 1031-1033, 2004

[11] H. J. Unold. S. W. Z. Mahmoud, R. Jager, M. Grabherr, R. Micalzik and K. J. Ebeling, “Large area single mode VCSELs and the self aligned surface relief”, IEEE. Journal On Selected Topics in Quantum Electronics, vol. 7, pp. 386-392, 2001

[12] A. Haglund, J. S. Gustavsson, J. Vukusic, P. Modh and A. Larsson, “Single fundamental mode output power exceeding 6 mW from VCSELs with shallow surface relief”, IEEE Photonics Technology Letters, Vol. 16, pp. 368-370, 2004.

[13] H. Martinsson, J. Vukusic, M. Grabherr, R. Micalzik, R. Jager, K. J. Ebeleing and A. Larsson, “Transverse mode selection in large area oxide confined VCSELs using a shallow surface relief”, IEEE Photonics Technology Letters, vol. 11, pp. 1536-1538, 1999.

[14] J. Vukusic, H. Martinsson, J. S. Gustavsson and A. Larsson, “Numerical optimisation of the single fundamental mode output from a surface modified vertical cavity surface emitting laser”, IEEE Journal of Quantum Electronics, vol. 37, pp. 108-117, 2001

[15] See, for example, G. B. Stringfellow, “Organometallic Vapour Phase Epitaxy: Theory and Practice”, Academic Press (1994)

[16] A. Knigge, R. Franke, S. Knigge, B. Sumpf, K. Vogel, M. Zorn, M. Weyers and G. Trankle, “650 nm Vertical Cavity Surface Emitting Lasers: Laser Properties and Reliability Investigations”, Photonics Tech. Letters, vol. 14, pp. 1385-1387, 2002

[17] M. Watanabe, J. Rennie, M. Okajima and G. Hatakoshi, “Improvement in the temperature characteristics of 630 nm band InGaAlP multiquantum well laser diodes using a 15° misoriented substrate”, Electron. Lett. Vol. 29, pp. 250-252, 1993

[18] A. Valster, C. T. H. F. Liedenbaum, M. N. Finke, A. L. G. Severens, M. J. B. Boermans, D. W. E. Vandenhoudt and C. W. T. Bulle-Lieuwma “High Quality AlxGa1-x-yInyP Alloys Grown by MOVPE on (311) B GaAs Substrates”, Journal of Crystal Growth, Vol. 107, pp. 403-409, 1991

1. A vertical cavity surface emitting optical device comprising a cavity adapted for generating optical output having a wavelength in the range 630 nm to 690 nm. the device including an oxide aperture for concentrating electrical current within a central axial portion of the device and a surface relief feature at an output surface of the device adapted to select substantially a single lateral mode of operation.

2. The optical device of claim 1 in which the surface relief feature has a height in the range m)J4n where λ lies in the range 630 nm to 690 nm, m is an odd integer and n is the refractive index of the material in which the surface relief feature is formed at the wavelength λ.

3. The optical device of claim 1 in which the surface relief feature is provided as a step between a GaAs cap layer and an underlying InGaP etch stop layer or between an InGaAs cap layer and an AlGaInP etch stop layer.

4. The optical device of claim 1, in which the surface relief feature comprises a low relief portion centred on the optical axis.

5. The optical device of claim 1, in which the surface relief feature comprises a high relief portion centred on the optical axis.

6. The optical device of claim 1 in which the surface relief feature comprises a circular relief area centred on the central optical axis of the device and coaxial with the oxide aperture.

7. The optical device of claim 1 in which the diameter of the surface relief feature and the diameter of the oxide aperture are related by the expressions: y<x/8+4.25 and y<−4x/3+25.67, where x is the oxide aperture in microns and y is the surface relief diameter in microns.

8. The optical device of claim 7 in which the surface relief diameter is greater than 3 microns and the oxide aperture is greater than 6 microns.

9. The optical device of claim 1 in which the surface relief diameter is in the range 3 to 5 microns and the oxide aperture is in the range 6 to 15 microns.

10. The optical device of claim 1 in which the surface relief diameter is in the range 4.8 to 5 microns and the oxide aperture is in the range 8 to 9 microns.

11. The optical device of claim 1 comprising: a substrate; a lower reflector structure formed on the substrate; a quantum well structure over the lower reflector structure defining a cavity of the optical device; an upper reflector structure formed over the quantum well structure; and an upper layer or layers defining said surface relief feature.

12. The optical device of claim 11 in which the lower reflector structure comprises a distributed Bragg reflector mirror comprising 55 pairs of alternating layers of AlAs/Al(0.5)Ga(0.5)As, and wherein the upper reflector structure comprises a distributed Bragg reflector mirror comprising 35 pairs of alternating layers of Al(0.98-0.9S)GaAs/Al(0.5)GaAs.

13. The optical device of claim 12 in which one pair of the upper reflector structure layers utilises Al(0.9S)GaAs and the remaining 34 pairs of layers utilize Al(0.9S)GaAs as one of the constituents of each pair.

14. The optical device of claim 11 further including a diffusion barrier layer between the lower reflector structure and the quantum well structure.

15. The optical device of claim 11 further including a spacer layer between the quantum well structure and the upper reflector structure.

16. The optical device of claim 15 in which the spacer layer is doped with Mg.

17. The optical device of claim 11 in which the upper layer or layers defining said surface relief feature comprise a lower LnGaP etch stop layer and a quarter wavelength antiphase layer.

18. The optical device of claim 1 in which the surface relief feature has a height in the range 40 nm to 46 nm.

19. The optical device of any preceding claim comprising a VCSEL.

20. An optical device substantially as described herein with reference to the accompanying drawings.

21. The optical device of claim 2 in which the surface relief feature is provided as a step between a GaAs cap layer and an underlying InGaP etch stop layer or between an InGaAs cap layer and an AlGaInP etch stop layer.

22. The optical device of claim 2 in which the surface relief feature comprises a low relief portion centred on the optical axis.

23. The optical device of claim 3 in which the surface relief feature comprises a low relief portion centred on the optical axis.

24. The optical device of claim 2 in which the surface relief feature comprises a high relief portion centred on the optical axis.

25. The optical device of claim 3 in which the surface relief feature comprises a high relief portion centred on the optical axis.
